(19) United States
(12) Patent Application Publication
(10) Pub. No.: US 2017/0229635 A1
(43) Pub. Date: Aug. 10, 2017

(54) WIRED CIRCUIT BOARD

(71) Applicant: NITTO DENKO CORPORATION, Osaka (JP)

(72) Inventors: Takahiro TAKANO, Osaka (JP); Takatoshi SAKAKURA, Osaka (JP); Tomoaki OKUNO, Osaka (JP)

(73) Assignee: NITTO DENKO CORPORATION, Osaka (JP)

(21) Appl. No.: 15/425,607

(22) Filed: Feb. 6, 2017

(30) Foreign Application Priority Data
Feb. 8, 2016 (JP) 2016-022161

(51) Int. Cl. H01L 41/053; G11B 5/48; H05K 1/18; H05K 1/11; H05K 1/09

(52) U.S. Cl. CPC H01L 41/053; H05K 1/111; H05K 1/09; H05K 1/181; G11B 5/4826; H05K 2201/0338; H05K 2201/10007

(57) ABSTRACT

The wired circuit board includes a conductive layer having a terminal; a gold plated layer provided on the surface of the terminal; and a solder layer provided on the surface of the gold plated layer and provided so that the terminal and the electronic component can be electrically connected. The solder layer is made of a solder composition containing Sn, Bi, Cu and/or Ni, and the thickness T_{solder} of the solder layer relative to the thickness T_{Au} of the gold plated layer is 16 or more.

### CROSS-REFERENCE TO RELATED APPLICATION

The present application claims priority from Japanese Patent Application No. 2016-022161 filed on Feb. 8, 2016, the contents of which are hereby incorporated by reference into this application.

### BACKGROUND OF THE INVENTION

Field of the Invention

The present invention relates to a wired circuit board, in particular, to a wired circuit board that is electrically connected with an electronic component.

Description of Related Art

It has been known that a wired circuit board is electrically connected with an electronic component such as a piezoelectric element.

For example, Japanese Unexamined Patent Publication No. 2014-106993 has proposed a substrate for suspension including an element connection terminal provided in a head region, and a solder member for an element provided on the element connection terminal and is connected to an actuator element, wherein the solder member for an element is formed from a Sn-57Bi-1Ag solder material.

The solder member for an element described in Japanese Unexamined Patent Publication No. 2014-106993 has increased its strength while having a melting point of 180° C. or less. Therefore, while preventing polarization of the actuator element at the time of reflowing the solder member for an element, excellent connection strength is ensured.

### SUMMARY OF THE INVENTION

Recently, more high connection strength is required for the solder member for the element in the substrate for suspension. However, with the substrate for suspension described in Japanese Unexamined Patent Publication No. 2014-106993, there are disadvantages in that the above-described requirements cannot be satisfied.

The present invention is to provide a wired circuit board having a low melting point but can ensure high connection strength with the electronic component.

The present invention (1) includes a wired circuit board including a conductive layer having a terminal; a gold plated layer provided on the surface of the terminal; and a solder layer provided on the surface of the gold plated layer, and provided so that the terminal and the electronic component can be electrically connected, wherein the solder layer is made of a solder composition containing Sn, Bi, and Cu and/or Ni, and the ratio of the thickness T_{solder} of the solder layer relative to the thickness T_{Au} of the gold plated layer is 16 or more.

The present invention (2) includes the wired circuit board of (1), wherein the thickness T_{Au} of the gold plated layer is 2.0 μm or less, and the thickness T_{solder} of the solder layer is 50 μm or less.

The present invention (3) includes the wired circuit board of (1) or (2), wherein the electronic component is a piezoelectric element.

With the wired circuit board of the present invention, the ratio of the thickness T_{solder} of the solder layer relative to the thickness T_{Au} of the gold plated layer (T_{solder}/T_{Au}) is high, and therefore the ratio of the solder composition forming the solder layer relative to the gold forming the gold plated layer can be made sufficiently high. Therefore, the alloy formed from the gold plated layer and the solder layer when the solder layer is heated to reflow ensures high mechanical strength. As a result, high connection strength between the terminal and the electronic component can be ensured.

### BRIEF DESCRIPTION OF THE DRAWINGS

FIG. 1 is a plan view of a suspension board with circuits as an embodiment of the wired circuit board of the present invention.

FIG. 2 is a cross-sectional view along line A-A of the suspension board with circuits shown in FIG. 1.

### DETAILED DESCRIPTION OF THE INVENTION

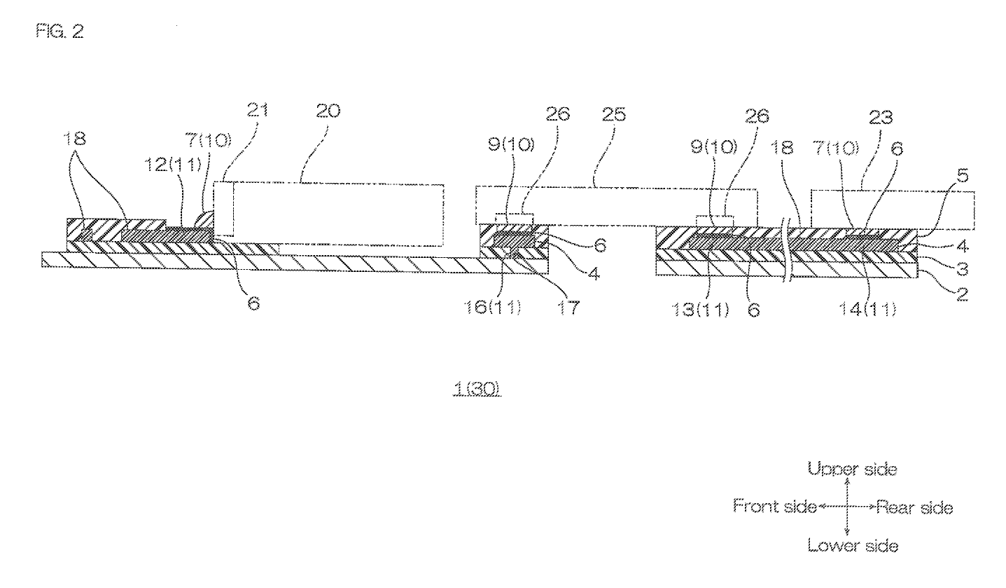

In FIG. 2, up-down direction in the plane of the paper is up-down direction (first direction, thickness direction), upper side in the plane of the sheet is upper side (one side in the first direction, one side in the thickness direction), lower side in the plane of the paper is lower side (the other side in the first direction, the other side in the thickness direction). In FIG. 2, left-right direction in the plane of the paper is front-rear direction (second direction perpendicular to first direction), left side in the plane of the sheet is front side (one side in the second direction), right side in the plane of the sheet is rear side (the other side in the second direction). In FIG. 2, direction in the plane of the paper thickness is width direction (third direction perpendicular to first direction and second direction), near side in the plane of the paper is left side (one side in third direction), and far side in the plane of the paper is right side (the other side in third direction). To be specific, the directions are in accordance with the direction arrows shown in Figures.

In the following, a suspension board with circuits as an embodiment of the wired circuit board of the present invention is described.

### 1. Suspension Board with Circuits

As shown in FIG. 2, a suspension board with circuits 1 includes a metal support layer 2, an insulating base layer 3, a conductive layer 4, an insulating cover layer 5, a gold plated layer 6, and a solder layer 10.

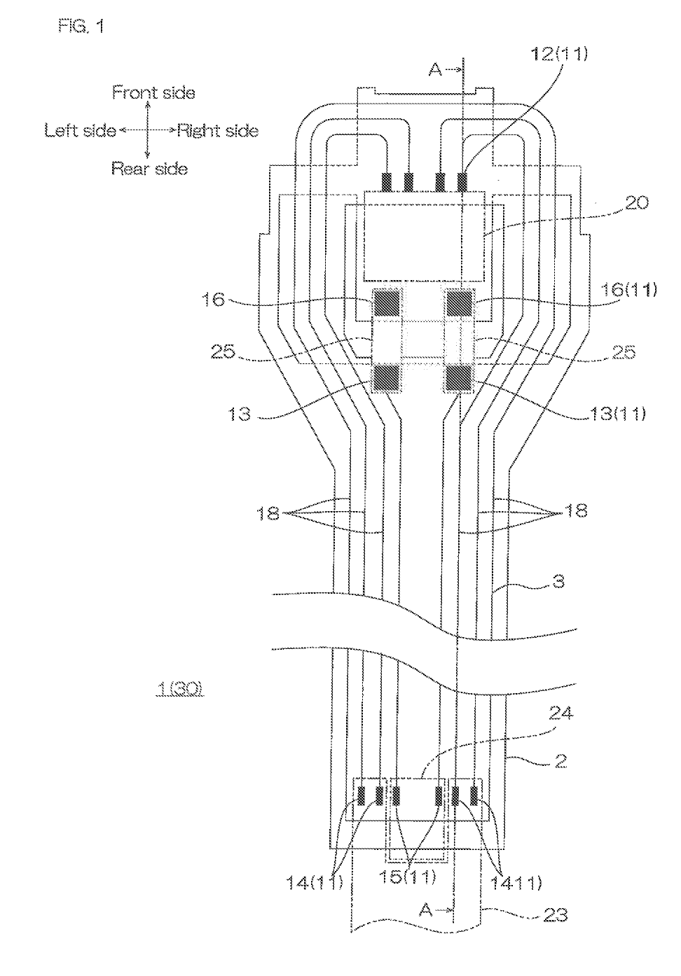

As shown in FIG. 1, the metal support layer 2 has a flat plate shape extending in the front-rear direction. The metal support layer 2 is made, for example, of a metal material such as stainless steel.

The insulating base layer 3 is provided on the metal support layer 2. The insulating base layer 3 has a pattern corresponding to the conductive layer 4 described next. The insulating base layer 3 is made, for example, of an insulating material such as polyimide.

The conductive layer 4 is provided on the insulating base layer 3. The conductive layer 4 includes a terminal 11 and a wire 18. The conductive layer 4 is made, for example, of a conductive material such as copper.

The terminal 11 has, as shown in FIG. 1, a magnetic head-side terminal 12, a piezoelectric element-side terminal 13, an external side terminal 14, a power source-side terminal 15, and a ground-side terminal 16.

The plurality of magnetic head-side terminals 12 are arranged in spaced-apart relation to each other in width direction at the front end portion of the insulating base layer 3.

The piezoelectric element-side terminals 13 are disposed at the rear side of the magnetic head-side terminal 12 at the front end portion of the insulating base layer 3. The plurality of piezoelectric element-side terminals 13 are arranged in line in spaced-apart relation to each other in width direction. The piezoelectric element-side terminals 13 are configured so as to be electrically connected with the electrodes 26 (described later) of the piezoelectric element 25.

The plurality of external side terminals 14 are arranged in line in spaced-apart relation to each other in width direction at the rear end portion of the insulating base layer 3.

The power source-side terminals 15 are disposed between the external side terminals 14 at the rear end portion of the insulating base layer 3. The plurality of power source-side terminals 15 are arranged in line in spaced-apart relation to each other in width direction.

The ground-side terminals 16 are disposed between the magnetic head-side terminal 12 and the piezoelectric element-side terminal 13 at the front end portion of the insulating base layer 3. The plurality of ground-side terminals 16 are disposed in spaced-apart relation to each other in width direction. As shown in FIG. 2, the lower end face of the ground-side terminal 16 is in direct contact with the top face of the metal support layer 2 exposed from the base opening 17 provided in the insulating base layer 3.

The plurality of wires 18 are disposed, as shown in FIG. 1, in spaced-apart relation to each other in width direction. The wires 18 electrically connect the magnetic head-side terminal 12 and the external side terminal 14. The wires 18 electrically connect the piezoelectric element-side terminal 13 and the power source-side terminal 15.

The insulating cover layer 5 is disposed, as shown in FIG. 2, on the insulating base layer 3 so as to cover the wires 18. The insulating cover layer 5 has a pattern that allows the terminals 11 to expose. To be specific, the insulating cover layer 5 has a shape that allows exposure of the piezoelectric element-side terminal 13, the external side terminal 14, the power source-side terminal 15, and the ground-side terminal 16. The insulating cover layer 5 is made of the same insulating material as that of the insulating base layer 3.

The gold plated layer 6 is provided on the surface of the terminal 11. The gold plated layer 6 is not provided on the surface of the wire 18. The gold plated layer 6 is made of gold. The gold plated layer 6 is composed mainly of gold, and may contain other sub components in a minute amount to the extent that does not substantially hinder the effects of the present invention. The gold plated layer 6 has a thickness TA, of for example, 0.1 pun or more, preferably 0.25 μm or more, and for example, 5 μm or less, preferably 2.5 μm or less, more preferably 2.0 μm or less.

When the gold plated layer 6 has a thickness T_{Au} of the above-described upper limit or less, the ratio (T_{solder}/T_{Au}) described later can be set lower to improve connection reliability of the second solder layer 9. When the gold plated layer 6 has a thickness T_{Au} of the above-described lower limit or more, the terminal 11 can be reliably protected.

The solder layer 10 is provided on the top face (surface) of the gold plated layer 6. The solder layer 10 has a first solder layer 7 and a second solder layer 9.

The first solder layer 7 is provided so as to correspond to the magnetic head-side terminal 12, the external side terminal 14, and the power source-side terminal 15. To be specific, the first solder layer 7 is provided on the top face of the gold plated layer 6 provided on the surface of the magnetic head-side terminal 12, the gold plated layer 6 provided on the surface of the external side terminal 14, and the gold plated layer 6 provided on the surface of the power source-side terminal 15. The first solder layer 7 is made of a high melting point solder having a melting point of, for example, 180° C. or more, furthermore, 200° C. or more.

The second solder layer 9 is provided in correspondence with the piezoelectric element-side terminal 13 and the ground-side terminal 16. To be specific, the second solder layer 9 is provided on the top face of the gold plated layer 6 provided on the surface of the piezoelectric element-side terminal 13 and the gold plated layer 6 provided on the surface of the ground-side terminal 16. The second solder layer 9 is made of a solder composition containing Sn, Bi, Cu and/or Ni.

The Sn content is the remaining portion of the Bi, Cu, and Ni contents described next.

The Bi content relative to the solder composition is, for example, 31 mass % or more, preferably 34 mass % or more, more preferably more than 35 mass %, further preferably 37 mass % or more. The Bi content relative to the solder composition is, for example, 59 mass % or less, preferably 57 mass % or less, more preferably 54 mass % or less, further preferably less than 50 mass %.

The Cu content relative to the solder composition is, for example, 0 mass % or more, preferably 0.3 mass % or more, more preferably 0.4 mass % or more. The Cu content relative to the solder composition is, for example, 1.0 mass % or less, preferably 0.8 mass % or less, more preferably 0.7 mass % or less. The Cu content relative to the Bi content (Cu/Bi) is, for example, 0.001 or more, preferably 0.01 or more, and for example, 0.1 or less, preferably 0.02 or less.

The Ni content relative to the solder composition is, for example, 0 mass % or more, preferably 0.01 mass % or more, more preferably 0.02 mass % or more. The Ni content relative to the solder composition is, for example, 0.06 mass % or less, preferably 0.05 mass % or less.

The Ni content relative to the Bi content (Ni/Bi) is, for example, 0.0002 or more, preferably 0.0005 or more, and 0.002 or less, preferably 0.001 or less.

To be specific, the solder composition contains, for example, Sn, Bi, Cu, and Ni. Alternatively, the solder composition contains, for example, Sn, Bi, and Cu, and does not contain Ni. Alternatively, the solder composition contains, for example, Sn, Bi, and Ni, and does not contain Cu.

Preferably, the solder composition contains Sn, Bi. Cu, and Ni. More preferably, the solder composition is made only of Sn, Bi, Cu, and Ni.

To be specific, examples of the solder composition include those represented by Sn-40Bi-(0 to 1.1) Cu-0.03Ni. For such a solder composition, a commercially available product can be used, and to be specific, ECO Solder Paste SHF L27-LT142ZH (manufactured by Senju Metal Industry Co., Ltd.) can be used.

The thickness T_{solder} of the second solder layer 9 is set so that the ratio of the thickness T_{solder} of the solder layer relative to the thickness T_{Au} of the gold plated layer (T_{solder}/T_{Au}) is 16 or more. The above-described ratio (T_{solder}/T_{Au}) is preferably 20 or more, more preferably 30 or more, further preferably 40 or more. The above-described ratio (T_{solder}/T_{Au}) is, for example, 100 or less.

When the ratio (T_{solder}/T^{Au}) is below the above-described lower limit, high connection strength between the piezoelectric element 25, the ground-side terminal 16, and the piezoelectric element-side terminal 13 cannot be ensured. When the ratio (T_{solder}/T^{Au}) is the above-described upper limit or less, interference with other components such as a load beam can be suppressed.

To be specific, the second solder layer 9 has a thickness T_{solder} of, for example, 5 μm or more, preferably 15 μm or more, more preferably 20 μm or more. The second solder layer 9 has a thickness T_{solder} of, for example, 50 μm or less, preferably 25 μm or less. When the second solder layer 9 has a thickness T_{solder} of the above-described upper limit or less, the above-described ratio (T_{solder}/T_{Au}) can be set lower to improve connection reliability of the second solder layer 9.

The solder composition has a melting point of, for example, 160° C. or less, preferably 150° C. or less. The solder composition has a melting point of for example, 110° C. or more, preferably 120° C. or more.

When the solder composition has a melting point of the above-described upper limit or less, disappearance of polarization of the piezoelectric element 25 can be suppressed.

To produce the suspension board with circuits 1, the metal support layer 2, the insulating base layer 3, the conductive layer 4, and the insulating cover layer 5 are formed sequentially by a known method.

Then, a gold plated layer 6 is provided, on the surface of the terminal 11 by, for example, electroplating, or electroless plating.

Thereafter, the solder layer 10 is provided on the surface of the gold plated layer 6.

To be specific, the first solder layer 7 is disposed on the surface of the gold plated layer 6 corresponding to the magnetic head-side terminal 12, the external side terminal 14, and the power source-side terminal 15. The second solder layer 9 is disposed on the surface of the gold plated layer 6 corresponding to the piezoelectric element-side terminal 13 and the ground-side terminal 16.

The suspension board with circuits 1 is produced in this manner.

Thereafter, on the suspension board with circuits 1, a slider 20 on which a magnetic head 21 is mounted, an external circuit board 23, a power source 24 (ref: FIG. 1), and a piezoelectric element 25 are mounted.

That is, the slider 20 is disposed at the front end portion of the suspension board with circuits 1, and the terminal of the magnetic head 21 is allowed to contact the first solder layer 7 corresponding to the magnetic head-side terminal 12. The external circuit board 23 is disposed at the rear end portion of the suspension board with circuits 1, and the terminal of the external circuit board 23 is allowed to contact the first solder layer 7 corresponding to the external side terminal 14. The power source 24 (ref: FIG. 1) is disposed at the rear end portion of the suspension board with circuits 1, and the terminal of the power source 24 is allowed to contact the second solder layer 9 corresponding to the power source-side terminal 15.

The piezoelectric element 25 has a flat plate shape extending in the front-rear direction. At the lower face of the both front-rear end portions of the piezoelectric element 25, the electrode 26 is provided.

Then, as shown in FIG. 1, the piezoelectric element 25 is disposed at the front end portion of the suspension board with circuits 1, and the electrode 26 of the piezoelectric element 25 is allowed to contact the second solder layer 9 corresponding to the piezoelectric element-side terminal 13 and the ground-side terminal 16.

Thereafter, laser is applied to the first solder layer 7, or a soldering iron is allowed to contact the first solder layer 7 to heat the first solder layer 7 at high temperature, thereby melting the first solder layer 7, and electrically connecting the magnetic head 21 with the magnetic head-side terminal 12. The external circuit board 23 is electrically connected with the external side terminal 14 in the same manner, and the power source 24 is electrically connected with the power source-side terminal 15 in the same manner.

Thereafter, the suspension board with circuits 1 is heated at low temperature to allow the second solder layer 9 to reflow. To be specific, the suspension board with circuits 1 is put into a reflow oven.

The temperature in the reflow oven is, for example, 160° C. or more, preferably 170° C. or more, and for example, 210° C. or less, preferably 200° C. or less. The suspension board with circuits 1 is put in the reflow oven for, for example, 1 minute or more, preferably 2 minutes or more, and for example, 20 minutes or less, preferably 15 minutes or less.

In this manner, the second solder layer 9 is subjected to reflowing. At this time, gold of the gold plated layer 6 corresponding to the second solder layer 9 and the solder composition forming the second solder layer 9 form, although not shown, an alloy. This alloy allows the electrode 26 of the piezoelectric element 25 to electrically connect the piezoelectric element-side terminal 13 with the ground-side terminal 16 strongly.

The suspension board with circuits 1, the slider 20, and the piezoelectric element 25 are included in a head gimbal assembly 30. To be specific, the head gimbal assembly 30 includes the suspension board with circuits 1, and the slider 20, the external circuit board 23, the power source 24, and the piezoelectric element 25 which are mounted on the suspension board with circuits 1. The head gimbal assembly 30 is mounted, for example, on a hard disk drive (not shown).

### 2. Operations and Effects of the Embodiment

With the suspension board with circuits 1, the ratio of the thickness T_{solder of} the second solder layer 9 relative to the thickness T_{Au} of the gold plated layer 6 (T_{solder}/T_{Au}) is high, and therefore the ratio of the solder composition forming the second solder layer 9 relative to gold forming the gold plated layer 6 can be set high sufficiently. Therefore, when the second solder layer 9 is heated to be subjected to reflowing, the alloy formed from the gold plated layer 6 and the second solder layer 9 can ensure a high mechanical strength. As a result, high connection strength between the piezoelectric element-side terminal 13 and the ground-side terminal 16 with the electrode 26 of the piezoelectric element 25 can be ensured.

### 3. Modified Example

In the embodiment, the first solder layer 7 is made of a high melting point solder. However, in a modified example, the first solder layer 7 is also made of the solder composition forming the second solder layer 9. That is, both of the first solder layer 7 and the second solder layer 9 are made of the above-described solder composition.

In the embodiment, first, the first solder layer 7 is heated, and thereafter, the second solder layer 9 is heated. However, the sequence is not particularly limited. For example, it is also possible to first heat the second solder layer 9, and thereafter, the first solder layer 7 can be heated.

In the embodiment, a piezoelectric element 25 is given as an example of the electronic component. However, the electronic component is not limited the piezoelectric element 25, and as an electronic component, for example, a resistor, a condenser, and a laser light emitting device can also be used.

In the embodiment, the piezoelectric element 25 is disposed above the conductive layer 4. However, in the modified example, although not shown, the piezoelectric element 25 can be disposed below the conductive layer 4. That is, the piezoelectric element 25 is positioned at a lower side portion in the suspension board with circuits 1. An opening is provided in the metal support layer 2 and an opening to allow the piezoelectric element-side terminal 13 to be exposed to the lower side is provided in the insulating base layer 3. The electrode 26 of the piezoelectric element 25 is provided on the top face of the both front-rear end portion of the piezoelectric element 25. Then, the electrode 26 is electrically connected to the piezoelectric element-side terminal 13 through the second solder layer 9 in the above-described two openings.

The sequence of the contact of the slider 20 to the first solder layer 7, the contact of the external circuit board 23 to the first solder layer 7, the contact of the power source 24 to the first solder layer 7, and the contact of the piezoelectric element 25 to the second solder layer 9 is not limited to the embodiment.

In the embodiment, the wired circuit board of the present invention is described as a suspension board with circuits 1. However, for example, as an example of the wired circuit board, a flexible wired circuit board including a reinforcing layer at the reverse face can also be used.

### EXAMPLE

In the following, the present invention is described further in detail with reference to Examples and Comparative Examples. However, the present invention is not limited to these Examples and Comparative Examples. The specific numeral values used in the description below such as mixing ratios (contents), physical property values, and parameters can be replaced with the lower limit (numeral values defined with “or more”, “more than”) of corresponding mixing ratios (contents), physical property values, and parameters in the above-described Description of Embodiments.

### Example 1

First, a metal support layer 2 made of a stainless steel and having a thickness of 20 pan, an insulating base layer 3 made of polyimide and having a thickness of 10 μm, a conductive layer 4 made of copper and having a thickness of 9 μm, and an insulating cover layer 5 made of polyimide and having a thickness of 4 μm were formed sequentially.

Then, a gold plated layer 6 having a thickness T_{Au} of 0.5 μm was formed on the surface of the terminal 11 of the conductive layer 4 by electroplating of gold.

Thereafter, a second solder layer 9 made of ECO Solder Paste SHF L27-LT142ZH (Sn (content: remaining portion), Bi (content: 40±1 mass %), Cu (content: 0.5±0.1 mass %), Ni (content: 0.03±0.01 mass %), manufactured by Senju Metal Industry Co., Ltd.) and having a thickness T_{solder} of 11 μm was formed on the top face of the gold plated layer 6 corresponding to the piezoelectric element-side terminal 13. Then, the rear end portion of the piezoelectric element 25 was disposed to face the above-described second solder layer 9.

Thereafter, the suspension board with circuits 1 is put into a reflow oven of 190° C. for 3 minutes to reflow the second solder layer 9. At this time, an alloy based on melting of the second solder layer 9 and the gold plated layer 6 is formed. In this manner, the electrode 26 at the rear end portion of the piezoelectric element 25 is allowed to connect with the piezoelectric element-side terminal 13. The electrode 26 at the front end portion of the piezoelectric element 25 is not connected to the ground-side terminal 16.

Thereafter, shear strength of the above-described alloy was measured. To be specific, the sensor is allowed to contact the front end portion of the piezoelectric element 25, and the sensor is pressed as is against the rear side relative to the piezoelectric element 25. The force (load) when the piezoelectric element 25 is removed from the piezoelectric element-side terminal 13 is evaluated as sear strength of the alloy of the second solder layer 9 and the gold plated layer 6.

### Example 4 to Comparative Example 4

Sear strength of the alloy of the second solder layer 9 and the gold plated layer 6 was measured in the same manner as in Example 1, except that the thickness T_{solder} of the second solder layer 9 was changed in accordance with Table 1.

The results of the sear strength measurement are shown in Table 1.

TABLE 1

| | Second solder layer | | Shear |
|---|---|---|---|
| | thickness T_{solder} (μm) | T_{solder}/T_{Au} | strength (g) |
| Example 1 | 11 | 22 | 61 |
| Example 2 | 17 | 34 | 58 |
| Example 3 | 21 | 42 | 80 |
| Example 4 | 21.5 | 43 | 69 |
| Comparative | 7.9 | 15.8 | 25 |
| Example 1 | | | |
| Comparative | 7.5 | 15 | 21 |
| Example 2 | | | |
| Comparative | 6.3 | 12.6 | 34 |
| Example 3 | | | |
| Comparative | 6 | 12 | 25 |
| Example 4 | | | |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A wired circuit board comprising:
a conductive layer having a terminal;
a gold plated layer provided on the surface of the terminal; and
a solder layer provided on the surface of the gold plated layer, and provided so that the terminal and the electronic component can be electrically connected,
wherein the solder layer is made of a solder composition containing Sn, Bi, and Cu and/or Ni, and
the ratio of the thickness T_{solder} of the solder layer relative to the thickness T_{Au} of the gold plated layer is 16 or more.

2. The wired circuit board according to claim 1, wherein the thickness T_{Au} of the gold plated layer is 2.0 μm or less, and
the thickness T_{solder} of the solder layer is 50 μm or less.

3. The wired circuit board according to claim 1, wherein the electronic component is a piezoelectric element.
